(19) United States
(12) Patent Application Publication
(10) Pub. No.: US 2008/0101022 A1
(43) Pub. Date: May 1, 2008

(54) Micro-fluidic cooling apparatus with phase change

(75) Inventor: Andrei Cernasov, Ringwood, NJ (US)

Correspondence Address: Kurt Luther;HONEYWELL INTERNATIONAL INC., Law Department AB 2, P.O. Box 2245, Morristown, NJ, 07962-9806, US

(73) Assignee: HONEYWELL INTERNATIONAL INC.

(21) Appl. No.: 11/586,664

(22) Filed: Oct. 26, 2006

(51) Int. Cl. H05K 7/20

(52) U.S. Cl. 361/699

(57) ABSTRACT

A cooling apparatus (100) for transferring heat away from a hot system (30) includes: a frame (125) having a plurality of channels (102) formed therein, the frame (125) extending between a thermally conductive hot element (105) and a thermally conductive cooling element (107); and a liquid coolant (113) contained within the channels (102) of the frame (125). Bubbles form as a result of the liquid coolant (113) reaching its vaporization temperature during operation of the hot system (30). The apparatus (100) creates a force that moves the bubbles away from the hot element (105) toward the cooling element (107).

### BACKGROUND OF THE INVENTION

1. Field of the Invention

The present invention relates to a cooling system, and more particularly to a micro-fluidic cooling apparatus using phase change.

2. Description of the Related Art

Electrical and mechanical systems used in complex environments such as aerospace environments, industrial environments, etc. typically include a large number of electrical and mechanical components to perform complex functions. For electrical systems, one unfortunate side effect of the ever-increasing circuit and board density levels is a commensurate increase in power dissipation. To mitigate the problem of power dissipation, a number of well-established cooling methods such as passive conduction cooling and forced liquid convection are used. Passive conduction cooling, however, does not exhibit sufficient cooling performance for many applications. Although forced convection can provide effective performance, moving mechanical parts in these systems, such as fans, pumps, etc., have lower reliability and often occupy a large space.

A disclosed embodiment of the present invention addresses these and other drawbacks by implementing a micro-fluidic cooling apparatus that uses phase change. The micro-fluidic cooling apparatus replaces the mechanical pump normally used in forced convection cooling with an electrokinetic pump, which circulates a liquid coolant between a thermally conductive hot element and a thermally conductive cold element. The hot element includes bubble nucleation sites, at which bubbles form when the hot element reaches a high enough temperature to vaporize the circulating liquid coolant. These bubbles are released from the nucleation sites and move toward the cold element, shrinking and eventually collapsing as their temperature drops. This process efficiently removes heat from the hot element, thereby regulating the temperature of the hot system.

### SUMMARY OF THE INVENTION

In one aspect, the present invention is a cooling apparatus for transferring heat away from a hot system. The cooling apparatus comprises: a frame having a plurality of channels formed therein, the frame extending between a hot element and a cooling element; a liquid coolant contained within channels of the frame; and elements for creating a force that causes bubbles to move from the hot element toward the cooling element.

According to another aspect, the present invention is a cooling apparatus for transferring heat away from a hot system, the cooling apparatus comprising: a frame having a plurality of channel pairs formed therein, the frame extending between a thermally conductive hot element and a thermally conductive cooling element, each channel pair forming a liquid circulation path between the hot element and the cooling element; a dielectric liquid coolant contained within channels of the frame; bubble nucleation sites located proximate the hot element, bubbles being formed at the bubble nucleation sites when the dielectric liquid coolant reaches its vaporization temperature during operation of the hot system; and electrodes arranged between the hot element and the cooling element, the electrodes creating a dielectrophoretic force that moves bubbles away from the hot element toward the cooling element.

### BRIEF DESCRIPTION OF THE DRAWINGS

Further aspects and advantages of the present invention will become apparent upon reading the following detailed description in conjunction with the accompanying drawings. These drawings do not limit the scope of the present invention. In these drawings, similar elements are referred to using similar reference numbers, wherein:

FIG. 1 is a general block diagram of a system containing a micro-fluidic cooling device according to an embodiment of the present invention;

FIG. 2 is a partial view of a micro-fluidic cooling device according to an embodiment of the present invention;

FIG. 3 is an additional partial view of a micro-fluidic cooling device illustrating bubble nucleation and heat removal according to an embodiment of the present invention;

FIG. 4 is an additional view of the micro-fluidic cooling device according to an embodiment of the present invention, illustrating stacked cooling device layers; and

FIG. 5 illustrates exemplary aspects of the operation of transporting bubbles from a hot element toward a cold element in a micro-fluidic cooling device according to an embodiment of the present invention.

### DETAILED DESCRIPTION

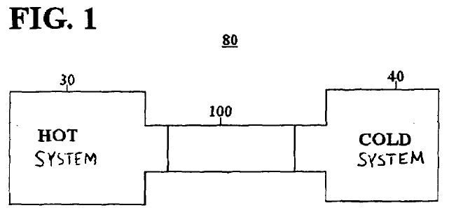

Aspects of the present invention are more specifically set forth in the following description with reference to the appended figures. FIG. 1 is a general block diagram of a system utilizing a micro-fluidic cooling device according to an embodiment of the present invention. The system 80 illustrated in FIG. 1 includes the following components: a hot system 30; a cold system 40; and a micro-fluidic cooling device 100. System 80 may be associated with a variety of environments, such as an electrical or mechanical system on-board an aircraft, in an industrial complex, in a laboratory facility, etc. In one exemplary implementation, the hot system 30 is an electronics assembly, which during operation emits sufficient heat to vaporize liquid coolant associated with the micro-fluidic cooling device 100. The cold system 40 is at a lower temperature than the vaporization temperature of the liquid coolant associated with the micro-fluidic cooling device 100. The cold system 40 may be, for example, a refrigerant system, a cold air system, a ventilated space, etc.

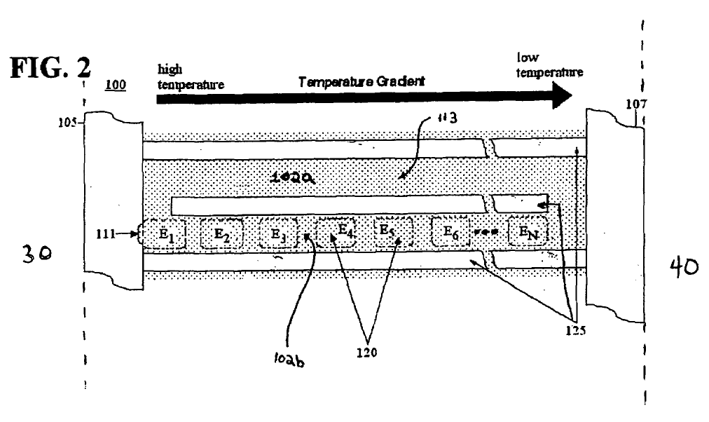

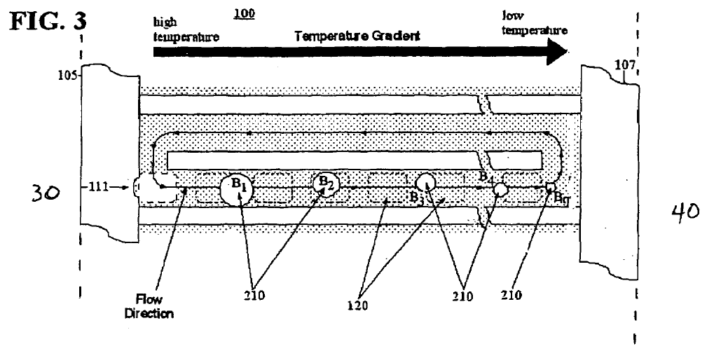

FIG. 2 is a partial view of a micro-fluidic cooling device 100 according to an embodiment of the present invention. The micro-fluidic cooling device 100 includes an arrangement of liquid coolant channels 102 within a heat conduction frame 125. FIG. 2 illustrates a pair of inter-connected channels, a “return” channel 102a and a “drive” channel 102b, which together form a path for circulating liquid coolant between the hot system 30 and the cold system 40. For ease of illustration, the partial view of FIG. 2 shows only one pair of inter-connected channels 102a, 102b. It should be recognized, however, that the micro-fluidic cooling device 100 according to an embodiment of the present invention includes numerous channel pairs, arranged side-by-side within the heat conduction frame 125. Design characteristics of the inter-connected channels (including the number of channel pairs and channel dimensions: e.g., 10 micron width), the heat conduction frame (e.g., dimensions, materials), and the liquid used as the liquid coolant will vary from environment to environment. Depending on the implementation environment, the heat conduction frame 125 may be formed of a rigid or highly-flexible material (e.g., having a “ribbon-like” appearance). As will be described below with reference to FIG. 3, the heat conduction frame 125 in one embodiment includes a plurality of layers, each layer having numerous side-by-side channel pairs 102a, 102b formed therein.

On one end, the heat conduction frame 125 contacts a thermally conductive hot element 105, such as a heat sink/plate, which transfers heat from the hot system 30 to the micro-fluidic cooling device 100. On the other end, the heat conduction frame 125 contacts a thermally conductive cold element 107, such as cold surface/plate associated with the cold system 40. As shown in FIG. 2, the micro-fluidic cooling device 100 further includes a plurality of electrodes 120, labeled E₁, E₂, E₃, E₄, E₅, E₆, . . . , E_{N}, which are formed within the heat conduction frame 125 under (or above) a drive channel 102b. As described in detail below, the micro-fluidic cooling device 100 achieves an electrokinetic pumping effect using the electrodes 120 (the associated power supply and control not being shown) to circulate a dielectric liquid coolant 113 within the corresponding channel pair 102a, 102b.

As shown in FIG. 2, the surface of the hot element 105 includes a bubble nucleation site 111 at a position in line with the drive channel 102b and in contact with the dielectric liquid coolant 113. Temperature varies along the length of the micro-fluidic cooling device 100 as shown by the temperature gradient arrow at the top of FIG. 2, from a high temperature at hot element 105, to a lower temperature at cold element 107. During operation, the hot element 105 heats dielectric liquid coolant 113 that is in proximity to the hot element 105. The cold element 107 cools dielectric liquid coolant 113 that is proximate the cold element 107. At relatively low temperatures of the hot element 105, most heat from the hot element 105 is conducted from the hot element 105 to the cold element 107 through the heat conduction frame 125 of the micro-fluidic cooling device 100. However, when the temperature of the hot element 105 approaches the boiling point of the dielectric liquid coolant 113 that fills the channels of the micro-fluidic cooling device 100, bubbles start forming at the bubble nucleation sites 111 located at the hot element 105. Once formed and released, the bubbles are transported by an electrical traveling wave towards the cold element 107 side. The electrical traveling wave is created using the plurality of electrodes 120 E₁, E₂, E₃, E₄, E₅, E₆, . . . , E_{N}. Capacitors (e.g., flexible capacitors) may be used for the plurality of electrodes 120. Additional details about the mechanics of bubble movement from the hot element 105 side to the cold element 107 side are described below with reference to FIGS. 3-5.

FIG. 3 is an additional partial view of the micro-fluidic cooling device 100 with phase change and bubble initialization, according to an embodiment of the present invention. In FIG. 3, the temperature of the hot element 105 side has reached the boiling point of the dielectric liquid coolant 113 filling the channels of the micro-fluidic cooling device 100. Under this operating condition, bubbles form at the bubble nucleation sites 111 located on the hot element 105. Bubbles B₁, B₂, B₃, . . . , B_{q} travel from the hot element 105 side to the cold element 107 side. The bubbles are transported by an electrical traveling wave generated by the plurality of electrodes 120. The travel direction is illustrated by the flow direction arrows in FIG. 3.

Bubbles are largest in size at the hot element 105 side. As bubbles move towards the cold element 107, they condensate and become smaller. As bubbles reach the cold element 107, the bubbles disappear as they transform back into liquid 113. The liquid 113 is then moved back towards the hot element 105 side, and the cycle repeats. The number of channel pairs 102a, 102b is a function of the desired amount of heat transfer from the hot element 105 to cold element 107. The greater the number of channels, the higher the cooling efficiency of micro-fluidic cooling device 100. In an exemplary embodiment, 50 to 100 channels are used for a display with flexible (“ribbon”) channels.

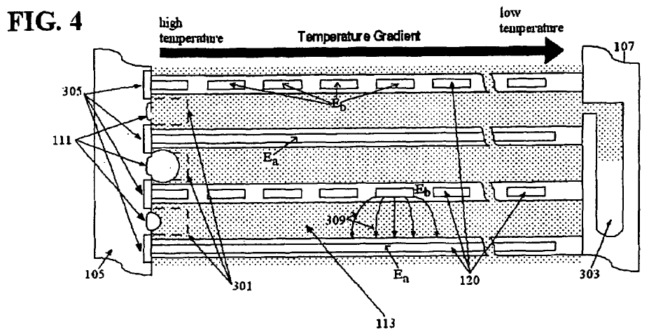

FIG. 4 is an additional view of a micro-fluidic cooling device 100 according to an embodiment of the present invention, illustrating stacked layers of the micro-fluidic cooling device 100. In FIG. 4, the temperature of the hot element 105 side has reached the boiling point of the dielectric liquid 113 filling the channels of the micro-fluidic cooling device 100, and bubbles form at the bubble nucleation sites 111 located on the hot element 105. The bubble nucleation sites 111 control the location where the bubbles are formed within the micro-fluidic cooling device 100, and control the size of the bubbles when they are released from the bubble nucleation sites 111. In an exemplary implementation, the bubble nucleation sites 111 are small indentations/dimples on the surface of the hot element 105. Each dimple may be located between a pair of thermal insulator regions 305 in the hot element 105, or dimples may be formed as indentations directly on a hot metal surface of the hot element 105. A two-dimensional array of dimples may be provided on the surface of the hot element 105. In one implementation, there is a one-to-one correspondence between bubble nucleation sites and longitudinal drive channels 102b of the micro-fluidic cooling device 100.

Once released from the bubble nucleation sites 111, bubbles are transported by an electrical traveling wave, via the liquid coolant 113, toward the cold element 107. Specifically, due to forces applied by the traveling wave, the liquid coolant 113 is caused to move toward the cold element 107, thereby displacing the bubbles in the same direction. This creates circulation in the channel pairs 102. As the bubbles travel towards the cold element 107 side, their temperature drops and, as a result, they shrink in size and eventually collapse. At the cold element 107 side, an expansion chamber 303 is provided to accommodate liquid coolant 113 displaced by bubble formation.

The dielectric liquid coolant 113 flows through the plurality of inter-channel passages 301 and replaces the space previously occupied by the departing bubbles. Local temperature of the dielectric liquid coolant 113 proximate to the hot element 105 at the inter-channel passages 301 is raised by heat from the hot element 105. Hence, the bubble formation and release cycle repeats to regulate temperature of the hot system 30. Because the latent heat of vaporization of a compound is generally much higher than its specific heat, heat removal by bubble formation, as described in the current application, is extremely efficient. As an example, while it takes 100 calories to raise the temperature of 1 gram of water from the freezing point (0 degree Celsius) to its boiling point (100 degree Celsius), it takes 540 calories to boil 1 gram of water away without any raise in temperature (i.e., at a constant 100 degree C.). Thus, the micro-fluidic cooling device 100 achieves effective cooling by controlling phase change of the dielectric liquid coolant 113 to the vapor state.

Depending on the application environment, various liquids can be used as the dielectric liquid coolant 113. For example, de-ionized water can be used for coolant liquid 113, with a boiling temperature of 100 degrees Celsius. A liquid salt may also be used for liquid coolant 113, with a boiling temperature on the order of 200 degrees Celsius. Such a liquid salt may be liquid sodium. Refrigerants may also be used for liquid coolant 113. Refrigerants have lower boiling temperatures, typically below 100 degree Celsius. Hence, if liquid coolant 113 is a refrigerant, the hot system 30 may be kept at a lower temperature, under 100 degrees Celsius, while still causing the refrigerant to boil and form bubbles.

Another cooling effect within the micro-fluidic cooling device 100 results from circulating the liquid coolant 113 between the hot element 105 and the cold element 107 side. This circulation is due to the movement of the bubbles created at the hot element 105 side, as well as to the kinetic engagement of the bubbles with the surrounding liquid coolant 113. The electrical traveling wave that transports bubbles from the hot element 105 side towards the cold element 107 side is generated using electrodes 120. FIG. 4 illustrates an electrode configuration for this purpose. Electrodes Eₐ have different electrical polarity than electrodes E_{b}. Hence, electrical field lines 309 are created between Eₐ and E_{b} electrodes.

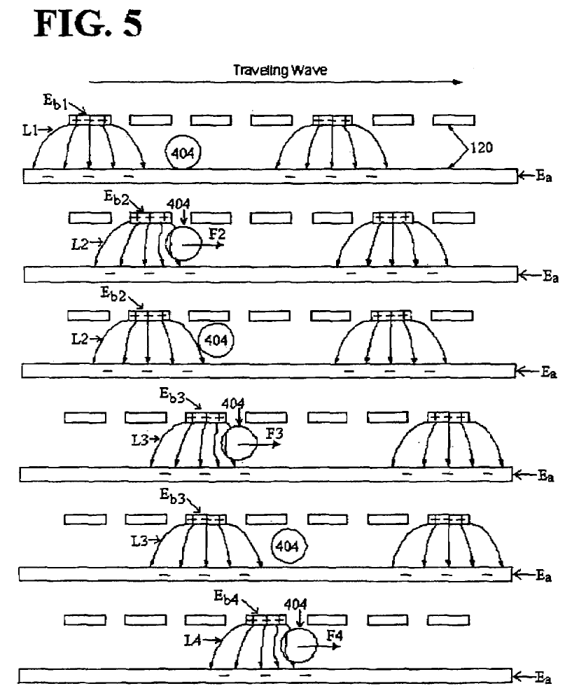

FIG. 5 illustrates exemplary aspects of the operation of transporting bubbles from the hot element 105 side to the cold element 107 side in a micro-fluidic cooling device 100 with phase change according to an embodiment of the present invention. FIG. 5 illustrates an electrokinetic method of transporting the bubbles using a dielectrophoretic bucket-brigade technique. Dielectrophoresis is a phenomenon in which a force is exerted on a dielectric particle when the particle is subjected to a non-uniform electric field. The dielectrophoretic force does not require that the particles be charged. The strength of the dielectrophoretic force depends strongly on the electrical properties of the dielectric particles, as well as the shape and size of particles and the frequency of the electric field.

The liquid coolant 113 is a dielectric liquid, filling the space around electrodes 120. The electric field generated by the electrodes 120 is non-uniform at the edges of the electrodes, as illustrated by the field lines 309 in FIG. 4. Hence, a dielectrophoretic force is exerted on the dielectric liquid coolant 113, the force being caused by the inhomogeneous nature of the electric field at the edges of the electrodes 120. The dielectrophoretic force on the liquid coolant 113 causes movement of the liquid coolant 113. In-rushing liquid coolant 113 causes eviction of the gas bubbles along the length of the micro-fluidic cooling device 100, hence making the gas bubbles formed at the nucleation sites 111 move towards the cold element 107 through the dielectric liquid coolant 113 having higher permittivity.

The electrokinetic method of transporting bubbles illustrated in FIG. 5 uses a dielectrophoretic bucket-brigade technique. The technique of a bucket brigade is used in the current invention to transfer motion to bubbles inside the dielectric liquid coolant 113. As illustrated in FIG. 5, at a time t a bubble 404 has arrived between electrodes 120. Positive electrode E_{b2} and a corresponding portion of the negative electrode Eₐ are turned on. Electric field L2 is generated between the energized electrodes. Since the electric field L2 is inhomogeneous at edges, a local dielectrophoretic force is exerted on dielectric coolant liquid 113 subjected to the non-uniform electric field L2. The local dielectric coolant liquid 113 moves under the effect of the dielectrophoretic force, consequently causing movement of the bubble 404 by a force F2. The bubble 404 is pushed towards the right by local force F2. When bubble 404 moves closer to the next positive electrode E_{b3}, positive electrode E_{b3} and a corresponding portion of negative electrode Eₐ are turned on. Inhomogeneous electric field L3 causes a local dielectrophoretic force on the local dielectric coolant liquid 113, and consequently bubble 404 is pushed by the dielectric liquid with force F3. In this manner, the bubble 404 moves longitudinally between electrodes 120, from the hot element 105 to cold element 107. The movement is piece-wise generated by local forces using sequential energization of pairs of electrodes, hence creating a dielectrophoretic bucked brigade movement. Furthermore, to control movement of each bubble 404, components (not shown) may be implemented for locating the bubble 404 positions. For instance, such components may be designed to locate bubble 404 positions by measuring the changing capacitances between negative electrode Eₐ and the positive electrodes E_{b1}, E_{b2}, E_{b3}, etc.

For proper operation, the field structures of the traveling wave are designed to be stable long enough for the bubble 404 to move outside the range of the active electrode. The electric fields in electrodes 120 that produce the bucket-brigade movement of bubble 404 are dependent on the breakdown voltage of the bubble gas. The breakdown voltage of the bubble gas is determined by the gas type. For example, the breakdown voltage of air is about 1 million Volts/meter. Hence, the width of the channel through which bubble 404 moves (the distance between positive electrode E_{b} and negative electrode Eₐ) is a function of the desired Voltage level applied to electrodes 120. For example, if 1000V are desired for electrodes 120, a 1 millimeter width channel is appropriate, and if 100V are desired for electrodes 120, a 100 micron width channel is appropriate. As the number of volts needed by the bucket-brigade to move the bubbles is related to the thickness of the channels of the micro-fluidic cooling device 100, the micro-fluidic cooling device 100 can be advantageously designed for high efficiency with a lower voltage and an appropriate width of channels for bubble movement.

The width of the channel through which bubble 404 moves may also be designed so as to limit effects of inertia on bubbles, so that bubble 404 can move through the channel without impediments. In one exemplary implementation, channels for bucket-brigade bubble movement are on the order of 100 microns.

Exemplary embodiments having been described above, it should be noted that such descriptions are provided for illustration only and, thus, are not meant to limit the present invention as defined by the claims below. Any variations or modifications of these embodiments, which do not depart from the spirit and scope of the present invention, are intended to be included within the scope of the claimed invention.

I claim:

1. A cooling apparatus for transferring heat away from a hot system, said cooling apparatus comprising:
a frame having a plurality of channels formed therein, said frame extending between a hot element and a cooling element;
a liquid coolant contained within said channels of said frame; and
elements for creating a force that causes bubbles to move from said hot element toward said cooling element.

2. The cooling apparatus according to claim 1, wherein said channels are arranged as a plurality of side-by-side channel pairs, each channel pair forming a circulation path for said liquid coolant between said hot element and said cooling element.

3. The cooling apparatus according to claim 1, wherein
said force is an electrokinetic force.

4. The cooling apparatus according to claim 3, wherein
said electrokinetic force is dielectrophoretic, and
said liquid coolant is delectric.

5. The cooling apparatus according to claim 4, wherein
said dielectrophoretic force is created by a non-uniform electric field from said electric elements, and
said electric elements include a plurality of electrodes arranged between said hot element and said cooling element.

6. The cooling apparatus according to claim 1, wherein said frame includes a plurality of layers and said channels are arranged as a plurality of channel pairs in said layers, each channel pair forming a circulation path for said dielectric liquid coolant between said hot element and said cooling element.

7. The cooling apparatus according to claim 1, wherein
said electrokinetic force is a dielectrophoretic force exerted on said bubbles from a non-uniform electric field created by said electric elements, and
said bubbles are moved from said hot element to said cooling element in a bucket-brigade of locally exerted dielectrophoretic forces.

8. The cooling apparatus according to claim 1, further comprising:
bubble nucleation sites located proximate said hot element, said bubbles being formed at said bubble nucleation sites when said liquid coolant reaches its vaporization temperature during operation of said hot system.

9. The cooling apparatus according to claim 8, wherein said bubble nucleation sites control size and location of bubble formation proximate said hot element.

10. The cooling apparatus according to claim 8, wherein each bubble nucleation site is aligned with a longitudinal channel used as a drive channel from said hot element toward said cooling element, such that there is a one-to-one correspondence between bubble nucleation sites and drive channels.

11. The cooling apparatus according to claim 10, wherein said drive channels have a size that is selected based on a voltage level applied to said electric elements.

12. The cooling apparatus according to claim 8, wherein said bubble nucleation sites are formed as a two-dimension array of dimples on a surface of said hot element.

13. The cooling apparatus according to claim 1, wherein said bubbles shrink in size and ultimately collapse during movement from said hot element to said cooling element in a repeating cycle.

14. The cooling apparatus according to claim 1, wherein
said frame is formed of flexible material.

15. A cooling apparatus for transferring heat away from a hot system, said cooling apparatus comprising:
a frame having a plurality of channel pairs formed therein, said frame extending between a thermally conductive hot element and a thermally conductive cooling element, each channel pair forming a liquid circulation path between said hot element and said cooling element;
a dielectric liquid coolant contained within said channels of said frame;
bubble nucleation sites located proximate said hot element, bubbles being formed at said bubble nucleation sites when said dielectric liquid coolant reaches its vaporization temperature during operation of said hot system; and
electrodes arranged between said hot element and said cooling element, said electrodes creating a dielectrophoretic force that moves said bubbles away from said hot element toward said cooling element.

16. The cooling apparatus according to claim 15, wherein said frame includes a plurality of layers and said channel pairs are arranged in said layers, thereby creating a multi-layered structure of circulation paths for said dielectric liquid coolant.

17. The cooling apparatus according to claim 15, wherein each bubble nucleation site is aligned with a longitudinal channel used as a return channel from said hot element toward said cooling element, such that there is a one-to-one correspondence between bubble nucleation sites and drive channels.

18. The cooling apparatus according to claim 17, wherein said drive channels have a size that is selected based on a voltage level applied to said electrodes.

19. The cooling apparatus according to claim 15, wherein said bubble nucleation sites are formed as a two-dimension array of dimples on a surface of said thermal conductor.

20. The cooling apparatus according to claim 15, wherein said bubbles shrink in size and ultimately collapse during movement from said hot element to said cooling element in a repeating cycle.
